(19) United States
(12) Patent Application Publication
(10) Pub. No.: US 2025/0341872 A1
(43) Pub. Date: Nov. 6, 2025

(54) DIMM HEAT SINK SYSTEM AND METHOD

(71) Applicant: Dell Products L.P., Round Rock, TX (US)

(72) Inventors: Robert J. Proulx, Holden, MA (US); Mauricio A. Sanchez, League City, TX (US)

(73) Assignee: Dell Products L.P., Round Rock, TX (US)

(21) Appl. No.: 18/652,158

(22) Filed: May 1, 2024

(51) Int. Cl. G06F 1/20; H05K 7/20

(52) U.S. Cl. CPC G06F 1/20; H05K 7/20254; H05K 7/20263; H05K 7/20454; H05K 7/2049; H05K 7/20509; G06F 2200/201

(57) ABSTRACT

Embodiments of the present disclosure provide systems and methods for component cooling using U-shaped heat bridges for conveying heat from the dual inline memory modules (DIMMs) to a thermally conductive member, for enhanced cooling. According to one embodiment, a DIMM cooling system includes one or more DIMM heat sinks each comprising a thermally conductive member, and one or more heat bridges configured on opposing sides of the thermally conductive member. The heat bridges are resilient in order to maintain contact with a pair of adjacent dual inline memory modules (DIMMs) configured in a DIMM array when disposed between the adjacent DIMMs.

### BACKGROUND

As the value and use of information continues to increase, individuals and businesses seek additional ways to process and store it. One option available to users is an Information Handling System (IHS). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated.

IHSs may be general or configured for a specific user or specific use, such as financial transaction processing, airline reservations, enterprise data storage, or global communications. In addition, IHSs may include a variety of hardware and software components that may be configured to process, store, and communicate information and may include one or more computer systems, data storage systems, and networking systems.

In recent years, as IHS components such as processors, graphics cards, random access memory (RAM), etc. have increased in clock speed and power consumption, the amount of heat produced by such components during normal operation has also increased. Often, the temperatures of these components need to be kept within a selected range to prevent overheating, instability, malfunction, and damage leading to a shortened component lifespan. Accordingly, cooling systems are often implemented in IHSs to cool certain high heat generating components.

To control the temperature of components of an IHS, one approach has been to implement a “passive” cooling system that serves to reject heat of a component by an airflow driven by one or more system-level air movers (e.g., fans, blowers, etc.). A different approach may include using an “active” cooling system in which a heat-exchanging cold plate is thermally coupled to one or more portions of the IHS, while a chilled liquid is passed through conduits internal to the cold plate to remove heat from those components.

### SUMMARY

Embodiments of the present disclosure provide systems and methods for component cooling using U-shaped heat bridges for conveying heat from the dual inline memory modules (DIMMs) to a thermally conductive member, for enhanced cooling. According to one embodiment, a DIMM cooling system includes one or more DIMM heat sinks each comprising a thermally conductive member, and one or more heat bridges configured on opposing sides of the thermally conductive member. The heat bridges are resilient in order to maintain contact with a pair of adjacent dual inline memory modules (DIMMs) configured in a DIMM array when disposed between the adjacent DIMMs.

According to another embodiment, an Information Handling System (IHS) includes a pair of adjacent dual inline memory modules (DIMMs) configured in a DIMM array, and a DIMM heat sink that includes a thermally conductive member, and one or more heat bridges configured on opposing sides of the thermally conductive member. The heat bridges are resilient in order to maintain contact with the adjacent DIMMs when disposed between the adjacent DIMMs.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIG. 1 illustrates an enlarged view of an example dual inline memory module (DIMM) heat sink that may be used for cooling a DIMM according to one embodiment of the present disclosure.

FIGS. 2A and 2B illustrate an example DIMM heat sink assembly that may be configured to actively cool an array of DIMMs according to one embodiment of the present disclosure.

FIG. 3 illustrates another embodiment of a DIMM heat sink that may be used for cooling DIMMs according to one embodiment of the present disclosure.

FIG. 4 illustrates yet another embodiment of a DIMM heat sink that may be used for cooling DIMMs according to one embodiment of the present disclosure.

FIG. 5 is a block diagram of certain components of an example IHS, which may be implemented with a DIMM heat sink system as described herein above.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

IHSs typically include system memory for storage of data and program code that the system's processor(s) may execute. Today's IHS designs have migrated toward the use of system memory in the form of dual inline memory modules (DIMMs) that can be coupled to a motherboard of the IHS using DIMM electrical connectors that are mechanically fixed to the motherboard. Each DIMM may include a DIMM printed circuit board (PCB) that includes multiple electrical contacts that electrically couple the components (e.g., Dynamic Random-Access Memory (DRAM)) on the DIMM PCB to the components on the motherboard.

Nevertheless, several factors exist to make cooling DIMMs challenging. For one reason, relatively little latitude in the form factor of DIMMs is available as their geometry is heavily specified by Joint Electron Device Engineering Council (JEDEC) to maintain interoperability among vendors. Additionally, density is prioritized as there is relatively little space between DIMMs. For example, many motherboards are designed to have a DIMM spacing of approximately 0.30 inches; thus, resulting in little room (e.g., 4 millimeters) between DRAM components on adjacent DIMMs. As such, there is not enough spacing to add a finned airflow solution. The relatively little spacing also forms a pressure drop when air cooling is utilized.

Solutions are limited due to the fact that DIMMs need to be serviceable. That is, they may need to be removed and replaced on the motherboard from time to time that often impacts the geometry and interface materials used. To allow DIMMs to be used in 1U servers, they are dimensioned to be short in order to keep the server within the confines of a 1U slot, and long so that they can support ten 10 DRAM components on the DIMM's PCB. Bulk temperature rise is also an issue for the DRAM components at the tailing edge of airflow across the DIMM's surface. Several different heights of components exist on a typical DIMM PCB, thus making heat sink solutions challenging as different gap pad materials with different thicknesses may be needed.

Yet another factor may include the ever-increasing level of heat load generated by DIMMs. For example, next generation DIMMs are expected to dissipate up to 20 Watts. In general, the approach for air cooling is to increase the airflow, but the airflow required can significantly increase fan usage and power consumption.

In the air-cooled space, attaching a cooling foil or slab to the DRAM components of the DIMMs has been considered. This approach adds some heat transfer area and spreads the heat from the hottest DRAM component toward cooler components, but the impact is limited as any improvement may come at the cost of pressure drop. Other more elaborate finned concepts have been posited, but their size typically limits their use in the 2U space. Gains in heat transfer are often partly undone by the negative impact of gap pads. In the liquid-cooled space, various systems involving cooling tubes and heat pipes have been proposed, but as with air cooled solutions, the effectiveness is often decreased by the impact of gap pads as described above.

In summary, to effectively cool DIMMs and similar electronic devices featuring bare components on PC boards, creating a strong thermal connection between its components and cooling medium is key. Additionally, the thermal connection should be thermally conductive, electrically isolating, and be able to contour around various devices, such as those components that may exist on DIMMs. As will be described in detail herein below, embodiments of the present disclosure provide systems and methods for component cooling using U-shaped heat bridges for conveying heat from the DIMMs to a thermally conductive member, such as a coolant pipe, thermally conductive plate, or thermally conductive fins.

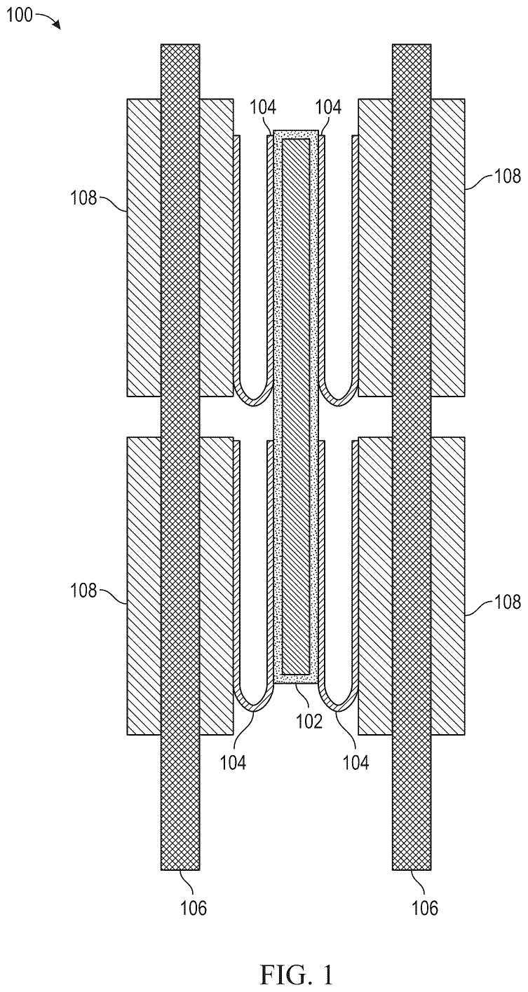

FIG. 1 illustrates an enlarged view of an example DIMM heat sink 100 that may be used for cooling DIMMs according to one embodiment of the present disclosure. As shown, the DIMM heat sink 100 includes a thin coolant pipe 102 coupled to several u-shaped heat bridges 104, and is configured in operative engagement between two DIMMs 106. Each DIMM 106 is configured with multiple DRAM chips 108 or other types of electrical components that generate heat during their operation. The heat bridges 104 are made of a resilient material such that they may deform slightly when the DIMM heat sink 100 is inserted between the two DIMMs 106, thus forming a relatively good thermal coupling with the DRAMs 108. In use, the heat bridges 104 convey heat away from the DRAMs 108 and towards the coolant pipe 102, which in turn, carries heat away from the DIMM heat sink 100 via a flow of coolant fluid through the coolant pipe 102. In one embodiment, a relatively small amount of low viscosity thermal grease or oil could be used to improve thermal contact between the heat bridge 104 and DRAM 108. While the heat bridges 104 are shown and described as having a U-shape, it should be appreciated that the heat bridges 104 may be formed in other shapes, such as an O-shaped configuration.

The coolant pipe 102 has a rectangular shape with a sufficiently thin profile in order to fit between two adjacent DIMMs 106, which are typically designed to have a spacing of about 0.3 inches on center. The coolant pipe 102 may be made of any suitable material. In one embodiment, the coolant pipe 102 may be made of a metal, such as copper, brass, or aluminum. In another embodiment, the coolant pipe 102 may be made of non-metallic materials, such as graphite or plastic.

The heat bridges 104 may be made of any suitable material that is sufficiently resilient for maintaining good contact with the DRAM 108 when the DIMM heat sink 100 is in operative engagement between two adjacent DIMMs 106. Examples of such materials may include a metal, such as copper, brass, or aluminum, or a non-metallic material, such as graphite or other suitable polymer material. The heat bridge 104 may be attached to the coolant pipe 102 using any suitable technique, such as weldment, brazing, soldering, or via an adhesive, such as epoxy.

In a particular embodiment, the heat bridges 104 may be made of copper due to its relatively good thermal conductive characteristics. To provide an example in which the heat bridges 104 are made of copper and are 20 milli-meters (mm) long, 0.2 mm thick, and 10 mm wide, simulation tests have shown that they would have a thermal resistance of about 7.0 degrees Celsius-per-Watt (C/W). Estimating an additional 0.5 C/W for the thermal interface between the heat bridge 104 and the DRAM 108, an estimated thermal resistance of 7.5 C/W would be sufficient for components with relatively low heat dissipation. Considering that the hottest DRAM heat loads are trending toward 0.4 Watts, the estimated 7.5 C/W yields an approximate 2.8 Celsius temperature rise from the DRAM 108 to the heat bridges 104, a value that could be considered reasonable. As can be seen from the simulation, the DIMM heat sink 100 may provide improved thermal coupling between the difficult to cool DIMM 106 and a cooling medium. Additionally, it may be made of commonly available materials, such as copper in some embodiments. The DIMM heat sink 100 may also block less airflow for cases where air cooling of DIMMs 106 or air cooling of other system components may be important. Some configurations may also be used to augment heat transfer and lower DRAM temperatures, which may result in lower fan flow and/or power requirements for a given DIMM heat load.

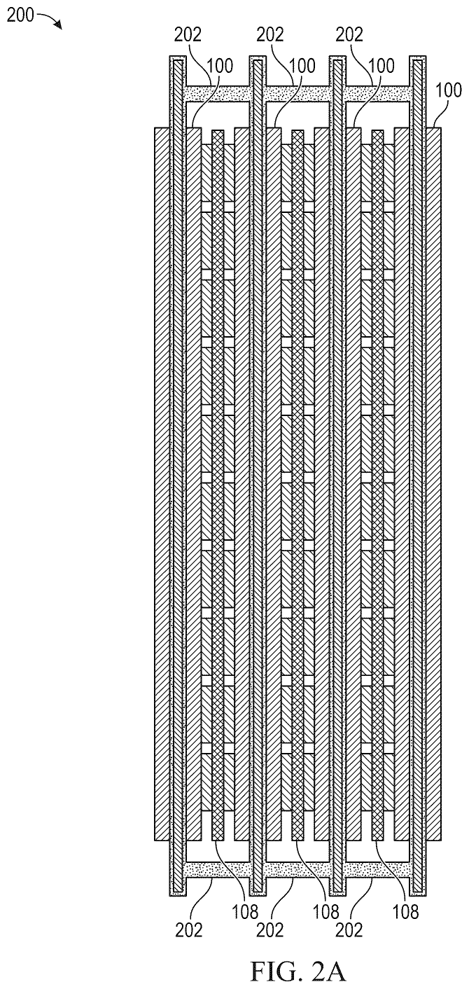

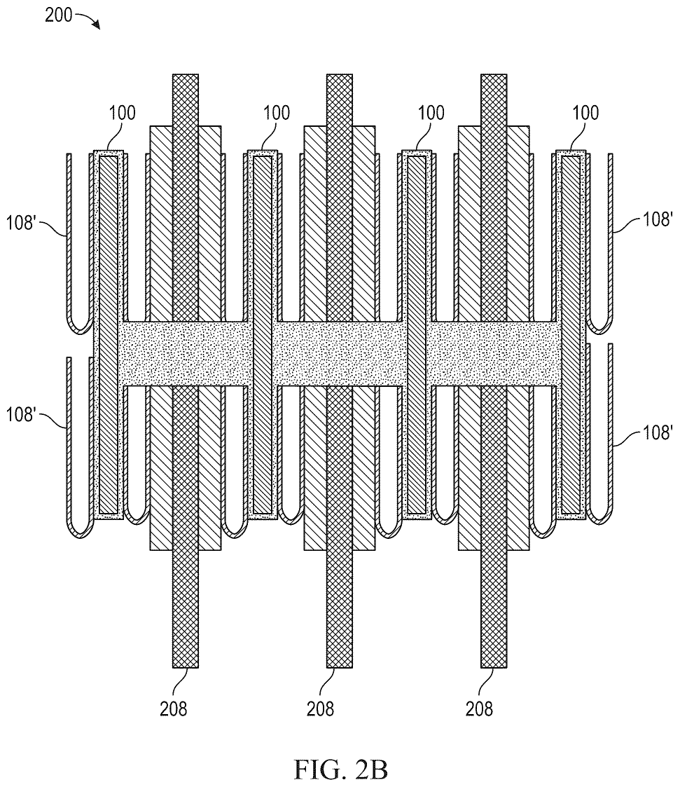

FIGS. 2A and 2B illustrate an example DIMM heat sink assembly 200 that may be configured to actively cool an array of DIMMs 108 according to one embodiment of the present disclosure. In particular, FIG. 2A shows a top view of the DIMM heat sink assembly 200, while FIG. 2B shows a side view of the DIMM heat sink assembly 200 in operational engagement over an array of the DIMMs 108. As shown, the DIMM heat sink assembly 200 is configured with four DIMM heat sinks 100 to provide cooling for three DIMMs 108. In other embodiments, the DIMM heat sink assembly 200 may be configured with any quantity of DIMM heat sinks 100 to provide cooling for any desired quantity of DIMMs 108, such as one, two, or four or more DIMMs 108. While the DIMM heat sink assembly 200 is shown with DRAM 108′ that are not thermally coupled to any DIMM 108, they may be removed if not needed or desired.

Interconnecting members 202 are provided at both ends of the DIMM heat sinks 100, and are attached between adjacent DIMM heat sink 100 at their coolant pipe 102. The interconnecting member 202 may be made of any desired rigid material that maintains a specified spacing distance between adjacent DIMM heat sinks 100. Additionally, the interconnecting member 202 may be useful for preventing splaying of the DIMMs 108 from their sockets that may otherwise be caused by the lateral pressure exerted on the DIMMs 108 by the heat bridge 104. Additionally, input and output manifolds (not shown) may be coupled to opposing ends of the coolant pipe 102 so that a coolant fluid may be circulated through the coolant pipe 102.

To use, the DIMM heat sink assembly 200 may be placed over an array of DIMMs 106 using sufficient force in order to cause the heat bridge 104 to deform slightly while they pushed into position adjacent to the DRAM 108 of the DIMMs 106. Input and output coolant fluid tubing may be coupled to the input and output manifolds, and a coolant fluid circulated through the coolant pipe 102. The DIMMs 106 may then be used in a normal manner while heat generated by the DRAM 108 is dissipated by the heat bridge 104 and the coolant fluid conveyed through the coolant pipe 102.

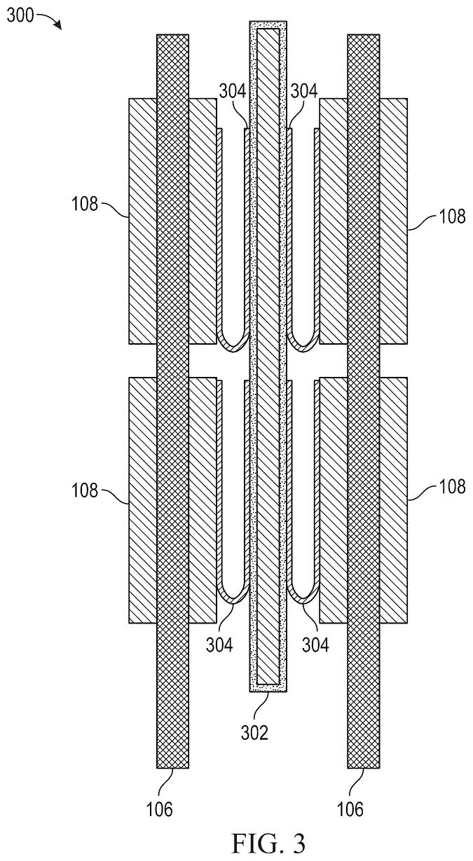

FIG. 3 illustrates another embodiment of a DIMM heat sink 300 that may be used for cooling DIMMs according to one embodiment of the present disclosure. As shown, the DIMM heat sink 300 may be disposed between adjacent DIMMs 106 in a similar manner that the DIMM heat sink 100 of FIG. 1 may be disposed. Additionally, the DIMM heat sink 300 includes multiple heat bridges 304 that are similar in design and construction to the heat bridge 104 of the DIMM heat sink 100 of FIG. 1. The DIMM heat sink 300 differs, however, in that it includes a thermally conductive plate 302 coupled between the heat bridges 304 that provides passive cooling for the DIMMs 106. That is, no coolant fluid is used to cool the DIMMs 106; rather, the thermally conductive plate 302 is used to transfer heat generated by the DIMMs 106 to the ambient environment. The thermally conductive plate 302 may be made of any thermally conductive material, such as copper, brass, aluminum, or graphite.

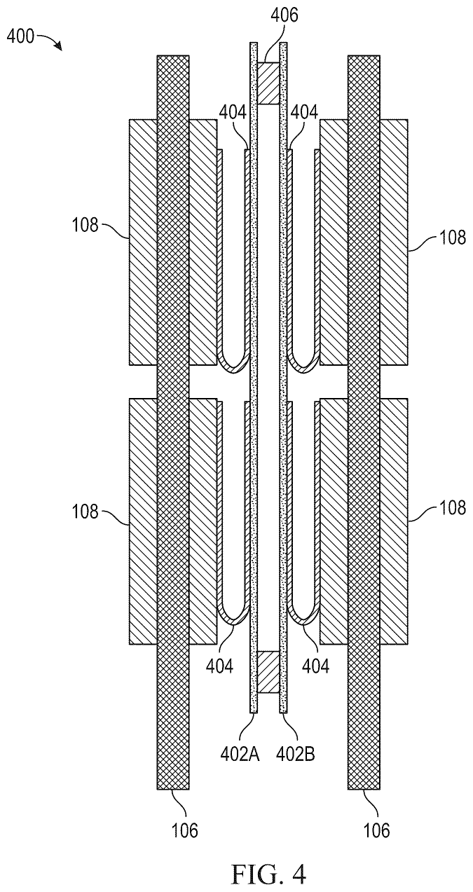

FIG. 4 illustrates yet another embodiment of a DIMM heat sink 400 that may be used for cooling DIMMs according to one embodiment of the present disclosure. As shown, the DIMM heat sink 400 may be disposed between adjacent DIMMs 106 in a similar manner that the DIMM heat sink 100 of FIG. 1 may be disposed. Additionally, the DIMM heat sink 400 includes multiple heat bridges 404 that are similar in design and construction to the heat bridge 104 of the DIMM heat sink 100 of FIG. 1. The DIMM heat sink 400 differs, however, in that it includes a pair of thermally conductive fins 402a-b (collectively 402) coupled between the heat bridges 404 that provides passive cooling for the DIMMs 106. The thermally conductive fins 402 may be made of any thermally conductive material, such as copper, brass, aluminum, or graphite. Spacers 406 may be configured between the 402 in order to maintain the fins 402 at a specified distance apart from one another.

Thus as can be seen from DIMM heat sinks 100, 300, and 400 of FIG. 1, 3, or 4, the heat bridges 104, 304, 404 may be used with any suitable type of thermally conductive member (e.g., coolant pipe 102, thermally conductive plate 304, or thermally conductive fins 404) to effectively cool the DIMMs 106 in an IHS.

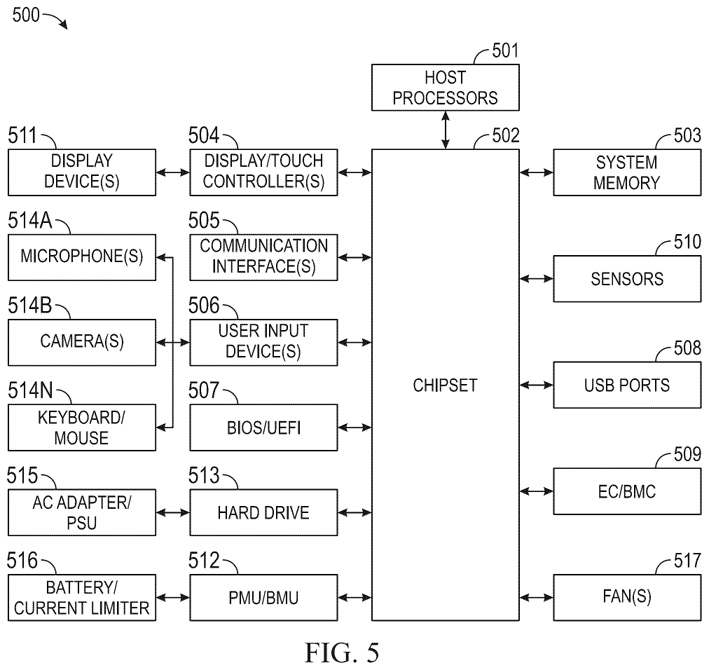

FIG. 5 is a block diagram of certain components of an example IHS 500, which may be implemented with a DIMM heat sink system described herein above. As depicted, IHS 500 includes host processor(s) 501. In various embodiments, IHS 500 may be a single-processor system, a multi-processor system including two or more processors, and/or a heterogeneous computing platform. Host processor(s) 501 may include any processor capable of executing program instructions, such as a PENTIUM processor, or any general-purpose or embedded processor implementing any of a variety of Instruction Set Architectures (ISAs), such as an x86 or a Reduced Instruction Set Computer (RISC) ISA (e.g., POWERPC, ARM, SPARC, MIPS, etc.).

IHS 500 includes chipset 502 coupled to host processor(s) 501. Chipset 502 may provide host processor(s) 501 with access to several resources. In some cases, chipset 502 may utilize a QuickPath Interconnect (QPI) bus to communicate with host processor(s) 501.

Chipset 502 may also be coupled to communication interface(s) 505 to enable communications between IHS 500 and various wired and/or wireless networks, such as Ethernet, WiFi, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

Communication interface(s) 505 may also be used to communicate with certain peripherals devices (e.g., BT speakers, microphones, headsets, etc.). Moreover, communication interface(s) 505 may be coupled to chipset 502 via a Peripheral Component Interconnect Express (PCIe) bus, or the like.

Chipset 502 may be coupled to display/touch controller(s) 504, which may include one or more Graphics Processor Units (GPUs) on a graphics bus, such as an Accelerated Graphics Port (AGP) or PCIe bus. As shown, display/touch controller(s) 504 provide video or display signals to one or more display device(s) 511.

Display device(s) 511 may include Liquid Crystal Display (LCD), Light Emitting Diode (LED), organic LED (OLED), or other thin film display technologies. Display device(s) 511 may include a plurality of pixels arranged in a matrix, configured to display visual information, such as text, two-dimensional images, video, three-dimensional images, etc. In some cases, display device(s) 511 may be provided as a single continuous display, or as two or more discrete displays.

Chipset 502 may provide host processor(s) 501 and/or display/touch controller(s) 504 with access to system memory 503. In various embodiments, system memory 503 may be implemented using any suitable memory technology, such as static RAM (SRAM), dynamic RAM (DRAM) or magnetic disks, or any nonvolatile/Flash-type memory, such as a solid-state drive (SSD) or the like.

Chipset 502 may also provide host processor(s) 501 with access to one or more Universal Serial Bus (USB) ports 508, to which one or more peripheral devices may be coupled (e.g., integrated or external webcams, microphones, speakers, etc.).

Chipset 502 may further provide host processor(s) 501 with access to one or more hard disk drives, solid-state drives, optical drives, or other removable-media drives 513.

Chipset 502 may also provide access to one or more user input devices 506, for example, using a super I/O controller or the like. Examples of user input devices 506 may include, but are not limited to, microphone(s) 514A, camera(s) 514B, and keyboard/mouse 514N. Other user input devices 506 may include a touchpad, trackpad, stylus or active pen, totem, etc.

Each user input devices 506 may include a respective controller (e.g., a touchpad may have its own touchpad controller) that interfaces with chipset 502 through a wired or wireless connection (e.g., via communication interfaces(s) 505). In some cases, chipset 502 may also provide access to one or more user output devices (e.g., video projectors, paper printers, 3D printers, loudspeakers, audio headsets, Virtual/Augmented Reality (VR/AR) devices, etc.). In certain embodiments, chipset 502 may further provide an interface for communications with hardware sensors 510.

Sensors 510 may be disposed on or within the chassis of IHS 500, or otherwise coupled to IHS 500, and may include, but are not limited to: electric, magnetic, radio, optical (e.g., camera, webcam, etc.), infrared, thermal (e.g., thermistors etc.), force, pressure, acoustic (e.g., microphone), ultrasonic, proximity, position, deformation, bending, direction, movement, velocity, rotation, gyroscope, Inertial Measurement Unit (IMU), and/or acceleration sensor(s).

The Unified Extensible Firmware Interface (UEFI) was designed as a successor to BIOS. As a result, many modern IHSs utilize UEFI in addition to or instead of a BIOS. As used herein, BIOS 507 is intended to also encompass a UEFI component.

Embedded Controller (EC) or Baseboard Management Controller (BMC) 509 is operational from the very start of each IHS power reset and handles various tasks not ordinarily handled by host processor(s) 501. Examples of these operations may include, but are not limited to: receiving and processing signals from a keyboard or touchpad, as well as other buttons and switches (e.g., power button, laptop lid switch, etc.), receiving and processing thermal measurements (e.g., performing fan control, CPU and GPU throttling, and emergency shutdown), controlling indicator LEDs (e.g., caps lock, scroll lock, number lock, battery, power, wireless LAN, sleep, etc.), managing PMU/BMU 512, alternating current (AC) adapter/Power Supply Unit (PSU) 515 and/or battery/current limiter 516, allowing remote diagnostics and remediation over network(s) 104, etc. For example, EC/BMC 509 may implement operations for interfacing with power adapter/PSU 515 in managing power for IHS 500. Such operations may be performed to determine the power status of IHS 500, such as whether IHS 500 is operating from AC adapter/PSU 515 and/or battery 516.

Firmware instructions utilized by EC/BMC 509 may also be used to provide various core operations of IHS 500, such as power management and management of certain modes of IHS 500 (e.g., turbo modes, maximum operating clock frequencies of certain components, etc.). In addition, EC/BMC 509 may implement operations for detecting certain changes to the physical configuration or posture of IHS 500. For instance, when IHS 500 is embodied as a 2-in-1 laptop/tablet form factor, EC/BMC 509 may receive inputs from a lid position or hinge angle sensor 510, and it may use those inputs to determine: whether the two sides of IHS 500 have been latched together to a closed position or a tablet position, the magnitude of a hinge or lid angle, etc. In response to these changes, the EC may enable or disable certain features of IHS 500 (e.g., front or rear facing camera, etc.).

In some cases, EC/BMC 509 may be configured to identify any number of IHS postures, including, but not limited to: laptop, stand, tablet, tent, or book. For example, when display(s) 511 of IHS 500 is open with respect to a horizontal keyboard portion, and the keyboard is facing up, EC/BMC 509 may determine IHS 500 to be in a laptop posture. When display(s) 511 of IHS 500 is open with respect to the horizontal keyboard portion, but the keyboard is facing down (e.g., its keys are against the top surface of a table), EC/BMC 509 may determine IHS 500 to be in a stand posture.

When the back of display(s) 511 is closed against the back of the keyboard portion, EC/BMC 509 may determine IHS 500 to be in a tablet posture. When IHS 500 has two display(s) 511 open side-by-side, EC/BMC 509 may determine IHS 500 to be in a book posture. When IHS 500 has two displays open to form a triangular structure sitting on a horizontal surface, such that a hinge between the displays is at the top vertex of the triangle, EC/BMC 509 may determine IHS 500 to be in a tent posture. In some implementations, EC/BMC 509 may also determine if display(s) 511 of IHS 500 are in a landscape or portrait orientation. In some cases, EC/BMC 509 may be installed as a Trusted Execution Environment (TEE) component to the motherboard of IHS 500.

Additionally, or alternatively, EC/BMC 509 may be configured to calculate hashes or signatures that uniquely identify individual components of IHS 500. In such scenarios, EC/BMC 509 may calculate a hash value based on the configuration of a hardware and/or software component coupled to IHS 500. For instance, EC/BMC 509 may calculate a hash value based on all firmware and other code or settings stored in an onboard memory of a hardware component.

Hash values may be calculated as part of a trusted process of manufacturing IHS 500 and may be maintained in secure storage as a reference signature. EC/BMC 509 may later recalculate the hash value for a component, compare it against the reference hash value to determine if any modifications have been made to the component, thus indicating that the component has been compromised. In this manner, EC/BMC 509 may validate the integrity of hardware and software components installed in IHS 500.

In various embodiments, IHS 500 may be coupled to an external power source (e.g., AC outlet or mains) through an AC adapter/PSU 515. AC adapter/PSU 515 may include an adapter portion having a central unit (e.g., a power brick, wall charger, or the like) configured to draw power from an AC outlet via a first electrical cord, convert the AC power to direct current (DC) power, and provide DC power to IHS 500 via a second electrical cord.

Additionally, or alternatively, AC adapter/PSU 515 may include an internal or external power supply portion (e.g., a switching power supply, etc.) connected to the second electrical cord and configured to convert AC to DC. AC adapter/PSU 515 may also supply a standby voltage, so that most of IHS 500 can be powered off after preparing for hibernation or shutdown, and powered back on by an event (e.g., remotely via wake-on-LAN, etc.). In general, AC adapter/PSU 515 may have any specific power rating, measured in volts or watts, and any suitable connectors.

IHS 500 may also include internal or external battery 516. Battery 516 may include, for example, a Lithium-ion or Li-ion rechargeable device capable of storing energy sufficient to power IHS 500 for an amount of time, depending upon the IHS's workloads, environmental conditions, etc. In some cases, a battery pack may also contain temperature sensors, voltage regulator circuits, voltage taps, and/or charge-state monitors. For example, battery 516 may include a current limiter, or the like.

In some embodiments, battery 516 may be configured to detect overcurrent or undervoltage conditions using Limits Management Hardware (LMH). As used herein, the term “overcurrent” refers to a condition in an electrical circuit that arises when a normal load current is exceeded (e.g., overloads, short circuits, etc.). Conversely, the term “undervoltage” refers to a condition (e.g., “brownout”) where the applied voltage drops to X % of rated voltage (e.g., 90%), or less, for a predetermined amount of time (e.g., 1 minute).

Power Management Unit (PMU) 512 governs power functions of IHS 500, including AC adapter/PSU 515 and battery 516. For example, PMU 512 may be configured to: monitor power connections and battery charges, charging batteries, control power to other components, devices, or ICs, shut down components when they are left idle, control sleep and power functions (On and Off), managing interfaces for built-in keypad and touchpads, regulate real-time clocks (RTCs), etc.

In some implementations, PMU 512 may include one or more Power Management Integrated Circuits (PMICs) configured to control the flow and direction or electrical power in IHS 500. Particularly, a PMIC may be configured to perform battery management, power source selection, voltage regulation, voltage supervision, undervoltage protection, power sequencing, and/or charging operations. It may also include a DC-to-DC converter to allow dynamic voltage scaling, or the like.

Additionally, or alternatively, PMU 512 may include a Battery Management Unit (BMU) (referred to collectively as “PMU/BMU 512”). AC adapter/PSU 515 may be removably coupled to a battery charge controller within PMU/BMU 512 to provide IHS 500 with a source of DC power from battery cells within battery 516 (e.g., a lithium ion (Li-ion) or nickel metal hydride (NiMH) battery pack including one or more rechargeable batteries). PMU/BMU 512 may include non-volatile memory and it may be configured to collect and store battery status, charging, and discharging information, and to provide that information to other IHS components.

Examples of information collected and stored in a memory within PMU/BMU 512 may include, but are not limited to: operating conditions (e.g., battery operating conditions including battery state information such as battery current amplitude and/or current direction, battery voltage, battery charge cycles, battery state of charge, battery state of health, battery temperature, battery usage data such as charging and discharging data; and/or IHS operating conditions such as processor operating speed data, system power management and cooling system settings, state of “system present” pin signal), environmental or contextual information (e.g., such as ambient temperature, relative humidity, system geolocation measured by GPS or triangulation, time and date, etc.), and BMU events.

Examples of BMU events may include, but are not limited to acceleration or shock events, system transportation events, exposure to elevated temperature for extended time periods, high discharge current rate, combinations of battery voltage, battery current and/or battery temperature (e.g., elevated temperature event at full charge and/or high voltage causes more battery degradation than lower voltage), etc.

In some embodiments, power draw measurements may be conducted with control and monitoring of power supply via PMU/BMU 512. Power draw data may also be monitored with respect to individual components or devices of IHS 500. Whenever applicable, PMU/BMU 512 may administer the execution of a power policy, or the like.

IHS 500 may also include one or more fans 517 configured to cool down one or more components or devices of IHS 500 disposed inside a chassis, case, or housing. Fan(s) 517 may include any fan inside, or attached to, IHS 500 and used for active cooling. Fan(s) 517 may be used to draw cooler air into the case from the outside, expel warm air from inside, and/or move air across a heat sink to cool a particular IHS component. In various embodiments, both axial and sometimes centrifugal (blower/squirrel-cage) fans may be used.

In other embodiments, IHS 500 may not include all the components shown in FIG. 5. In other embodiments, IHS 500 may include other components in addition to those that are shown in FIG. 5. Furthermore, some components that are represented as separate components in FIG. 5 may instead be integrated with other components, such that all or a portion of the operations executed by the illustrated components may instead be executed by the integrated component.

For example, in various embodiments described herein, host processor(s) 501 and/or other components of IHS 500 (e.g., chipset 502, display/touch controller(s) 504, communication interface(s) 505, EC/BMC 509, etc.) may be replaced by discrete devices within a heterogeneous computing platform. As such, IHS 500 may assume different form factors including, but not limited to: servers, workstations, desktops, laptops, appliances, video game consoles, tablets, smartphones, etc.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A dual inline memory module (DIMM) cooling system comprising:
a DIMM heat sink comprising:
a thermally conductive member; and
one or more heat bridges configured on opposing sides of the thermally conductive member, wherein the heat bridges are resilient in order to maintain contact with a pair of adjacent dual inline memory modules (DIMMs) configured in a DIMM array when disposed between the adjacent DIMMs.

2. The DIMM cooling system of claim 1, wherein the thermally conductive member comprises a coolant pipe configured to convey a coolant fluid.

3. The DIMM cooling system of claim 1, wherein the thermally conductive member comprises a thermally conductive plate.

4. The DIMM cooling system of claim 1, wherein the thermally conductive member comprises a pair of thermally conductive fins.

5. The DIMM cooling system of claim 1, further comprising a plurality of the DIMM heat sinks that are configured to be disposed between adjacent ones of three or more DIMMs.

6. The DIMM cooling system of claim 5, further comprising one or more interconnecting members configured between each adjacent DIMM heat sink, the interconnecting members configured to maintain each adjacent pair of DIMM heat sinks a specified distance apart.

7. The DIMM cooling system of claim 1, wherein each heat bridge comprises at least one of an U-shaped plate or an O-shaped plate.

8. The DIMM cooling system of claim 7, wherein the U-shaped plate is made of copper.

9. The DIMM cooling system of claim 1, wherein the heat bridges are resilient in order to maintain contact with a plurality of DRAMs configured on each DIMM.

10. The DIMM cooling system of claim 9, further comprising a layer of thermal grease or oil disposed between the heat bridges and the DRAMs.

11. An Information Handling System (IHS) comprising:
a pair of adjacent dual inline memory modules (DIMMs) configured in a DIMM array; and
a DIMM heat sink comprising:
a thermally conductive member; and
one or more heat bridges configured on opposing sides of the thermally conductive member, wherein the heat bridges are resilient in order to maintain contact with the adjacent DIMMs when disposed between the adjacent DIMMs.

12. The IHS of claim 11, wherein the thermally conductive member comprises a coolant pipe configured to convey a coolant fluid.

13. The IHS of claim 11, wherein the thermally conductive member comprises a thermally conductive plate.

14. The IHS of claim 11, wherein the thermally conductive member comprises a pair of thermally conductive fins.

15. The IHS of claim 11, further comprising a plurality of the DIMM heat sinks that are configured to be disposed between adjacent ones of three or more DIMMs.

16. The IHS of claim 15, further comprising one or more interconnecting members configured between each adjacent DIMM heat sink, the interconnecting members configured to maintain each adjacent pair of DIMM heat sinks a specified distance apart.

17. The IHS of claim 11, wherein each heat bridge comprises at least one of an U-shaped plate or an O-shaped plate.

18. The IHS of claim 17, wherein the U-shaped plate is made of copper.

19. The IHS of claim 11, wherein the heat bridges are resilient in order to maintain contact with a plurality of DRAMs configured on each DIMM.

20. The IHS of claim 19, further comprising a layer of thermal grease or oil disposed between the heat bridges and the DRAMs.
